(19) United States
(12) Patent Application Publication
(10) Pub. No.: US 2016/0240741 A1
(43) Pub. Date: Aug. 18, 2016

(54) LIGHT EMITTING COMPONENT

(71) Applicant: Genesis Photonics Inc., Tainan City (TW)

(72) Inventors: Yu-Chen Kuo, Tainan City (TW); Yan-Ting Lan, Tainan City (TW); Jing-En Huang, Tainan City (TW); Teng-Hsien Lai, Tainan City (TW); Kai-Shun Kang, Tainan City (TW)

(21) Appl. No.: 15/045,265

(22) Filed: Feb. 17, 2016

Related U.S. Application Data
(60) Provisional application No. 62/116,923, filed on Feb. 17, 2015.

(51) Int. Cl. H01L 33/38

(52) U.S. Cl. CPC H01L 33/382

(57) ABSTRACT

A light emitting component includes an epitaxial structure, a first electrode, a conducting layer and a second electrode. The epitaxial structure includes a substrate, a first semiconductor layer, a light emitting layer and a second semiconductor layer. The first electrode is disposed on the first semiconductor layer. The conducting layer is disposed on the second semiconductor layer and includes a first conducting area and a second conducting area, wherein a resistance of the first conducting area is smaller than a resistance of the second conducting area. The second electrode is disposed on the conducting layer and has an extension portion, wherein the extension portion extends toward the first electrode and the first conducting area overlaps at least a part of the extension portion.

### CROSS REFERENCE TO RELATED APPLICATION

This application claims the benefit of U.S. Provisional Application No. 62/116,923, which was filed on Feb. 17, 2015, and is incorporated herein by reference.

### BACKGROUND OF THE INVENTION

1. Field of the Invention

The disclosure relates to a light emitting component and, more particularly, to a light emitting component capable of enhancing the light emitting efficiency effectively.

2. Description of the Prior Art

Referring to FIG. 1, FIG. 1 is a schematic top view illustrating a conventional light emitting component 1. As shown in FIG. 1, the light emitting component 1 comprises an epitaxial structure 10, an N-type electrode 12, a conducting layer 14 and a P-type electrode 16, wherein the epitaxial structure 10 comprises an N-type semiconductor layer 18 and a P-type semiconductor layer 20. In general, the epitaxial structure 10 further comprises a light emitting layer (not shown) located between the N-type semiconductor layer 18 and the P-type semiconductor layer 20. The N-type electrode 12 is disposed on the N-type semiconductor layer 18, the conducting layer 14 is disposed on the P-type semiconductor layer 20, and the P-type electrode 16 is disposed on the conducting layer 14. The P-type electrode 16 has an extention portion 160 and the extention portion 160 extends toward the N-type electrode 12.

When a voltage is applied to the N-type electrode 12 and the P-type electrode 16, a current enters the P-type electrode 16, then flows through the P-type semiconductor layer 20, the light emitting layer and the N-type semiconductor 18, and then exits from the N-type electrode 12. However, the current is prone to flow through a path with smallest resistance as biasing. As shown in FIG. 1, since the extension portion 160 of the P-type electrode 16 is closer to the N-type electrode 12, the total resistance of a conducting path of the extension portion 160 is less than that of the remaining portion of the P-type electrode 16, therefore most current would flow toward the extension portion 160 having less resistance, and it further leads to the current crowding effect at the extension portion 160. In other words, the current is prone to enter the N-type semiconductor layer 18 through a site of the P-type electrode 16 much closer to the N-type electrode 12. Accordingly, the current entering the light emitting layer at a site of the P-type electrode 16 far away from the N-type electrode 12 has smaller current intensity, and the light emitting intensity at the site of the P-type electrode 16 far away from the N-type electrode 12 is less than the light emitting intensity at the site of the P-type electrode 16 closer to the N-type electrode 12. The aforementioned phenomenon would cause the light emitting component 1 to emit light not uniformly and then reduce the light emitting efficiency of the light emitting component 1.

### SUMMARY OF THE INVENTION

The disclosure provides a light emitting component capable of enhancing the current uniformity to solve the aforementioned problems.

The light emitting component of the disclosure comprises an epitaxial structure, a first electrode, a conducting layer and a second electrode. The epitaxial structure comprises a substrate, a first semiconductor layer, a light emitting layer and a second semiconductor layer. The first electrode is disposed on the first semiconductor layer. The conducting layer is disposed on the second semiconductor layer and the conducting layer comprises a first conducting area and a second conducting area, wherein a resistance of the first conducting area is less than a resistance of the second conducting area. The second electrode is disposed on the conducting layer and the second electrode has an extension portion, wherein the extension portion extends toward the first electrode and the first conducting area overlaps at least a part of the extension portion.

According to an embodiment of the disclosure, a thickness of the first conducting area may be larger a thickness of the second conducting area.

According to an embodiment of the disclosure, a dopant concentration of the first conducting area may be larger than a dopant concentration of the second conducting area.

As the above mentioned, in the disclosure, the conducting layer is divided into the first conducting area with smaller resistance and the second conducting area with larger resistance, and the first conducting area with smaller resistance overlaps at least a part of the extension portion of the second electrode. Accordingly, the current entering the second electrode can be spread uniformly and then the light emitting efficiency is enhanced. It should be noted that, in the disclosure, in order to achieve that the resistance of the first conducting area is smaller than the resistance of the second conducting area, the thickness of the first conducting area may be larger the thickness of the second conducting area or the dopant concentration of the first conducting area may be larger than the dopant concentration of the second conducting area, depending on practical applications.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view illustrating a light emitting component of the prior art.

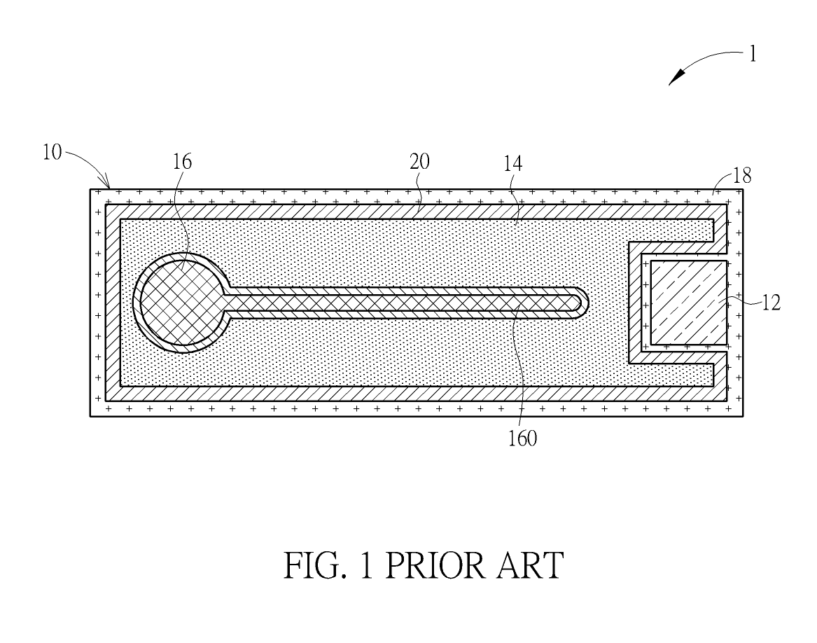

FIG. 2 is a schematic top view illustrating a light emitting component according to a first embodiment of the disclosure.

FIG. 3 is a schematic cross-sectional view illustrating the light emitting component shown in FIG. 2 along line X-X.

FIG. 4 is a schematic cross-sectional view illustrating a light emitting component according to a second embodiment of the disclosure.

FIG. 5 is a schematic cross-sectional view illustrating a light emitting component according to a third embodiment of the disclosure.

FIG. 6 is a schematic top view illustrating a light emitting component according to a fourth embodiment of the disclosure.

FIG. 7 is a schematic top view illustrating a light emitting component according to a fifth embodiment of the disclosure.

FIG. 8 is a schematic top view illustrating a light emitting component according to a sixth embodiment of the disclosure.

FIG. 9 is a schematic top view illustrating a light emitting component according to a seventh embodiment of the disclosure.

### DETAILED DESCRIPTION

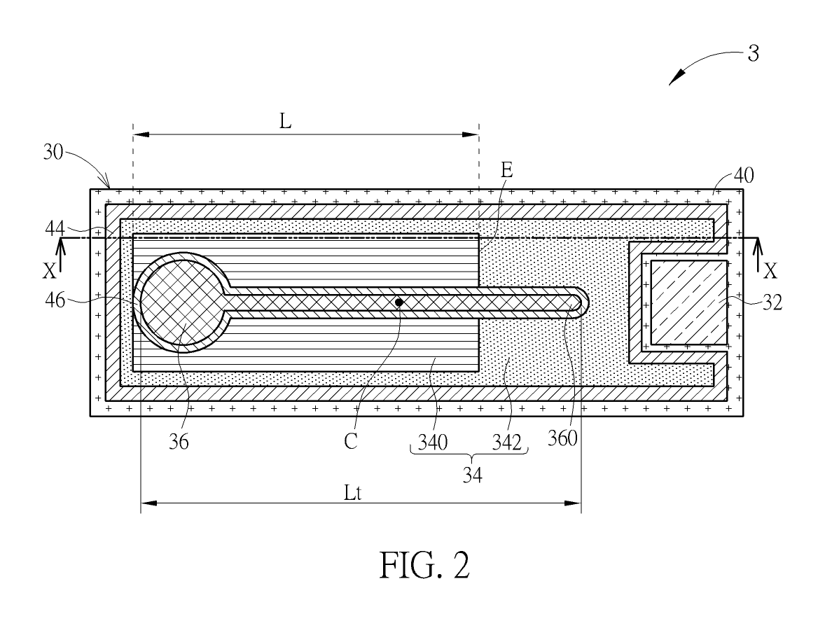

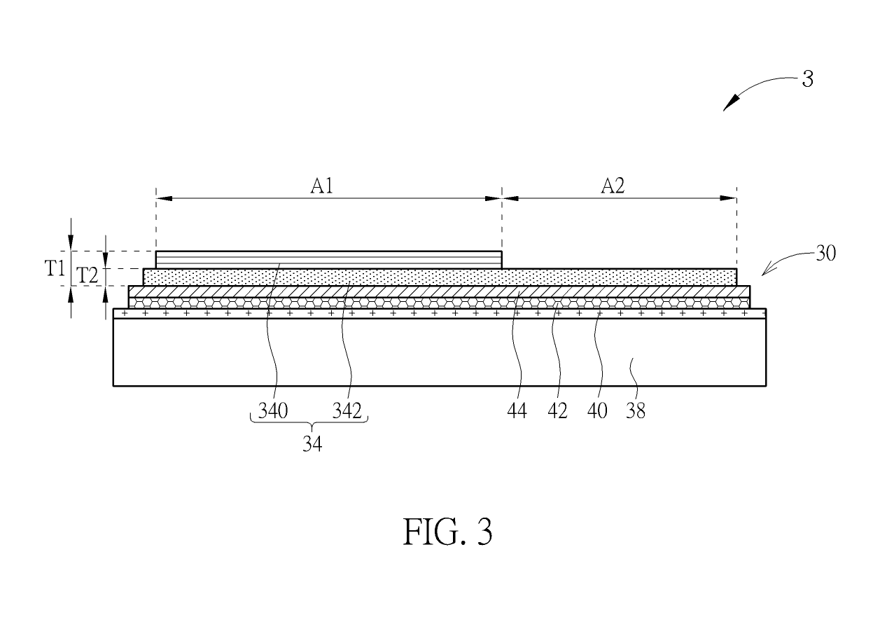

Referring to FIGS. 2 and 3, FIG. 2 is a schematic top view illustrating a light emitting component 3 according to a first embodiment of the disclosure and FIG. 3 is a schematic cross-sectional view illustrating the light emitting component 3 shown in FIG. 2 along line X-X. As shown in FIGS. 2 and 3, the light emitting component 3 comprises an epitaxial structure 30, a first electrode 32, a conducting layer 34 and a second electrode 36, wherein the epitaxial structure 30 comprises a substrate 38, a first semiconductor layer 40, a light emitting layer 42 and a second semiconductor layer 44. In practical applications, the light emitting component 3 may be a light emitting diode (LED). The first semiconductor layer 40 is located on the substrate 38, and the light emitting layer 42 is located on the first semiconductor layer 40, and the second semiconductor layer 44 is located on the light emitting layer 42. A material of the substrate 38 may be, but not limited to, sapphire. The first electrode 32 is disposed on the first semiconductor layer 40, and the conducting layer 34 is disposed on the second semiconductor layer 44, and the second electrode 36 is disposed on the conducting layer 34. The first semiconductor layer 40 may be an N-type semiconductor layer (e.g. N-type GaN layer) and the second semiconductor layer 44 may be a P-type semiconductor layer (e.g. P-type GaN layer). Meanwhile, the first electrode 32 may be an N-type electrode and the second electrode 36 may be a P-type electrode. A material of the conducting layer 34 may comprises indium tin oxide (ITO), ZnO or other conductive materials. Furthermore, the light emitting component 3 may further comprise a current block layer (CBL) disposed between the conducting layer 34 and the epitaxial structure 30 for providing current block function and improving the light emitting efficiency and the output light power of the light emitting component 3.

The conducting layer 34 comprises a first conducting area A1 and a second conducting area A2, wherein a thickness T1 of the first conducting area A1 is larger a thickness T2 of the second conducting area A2, therefore a resistance of the first conducting area A1 is smaller than a resistance of the second conducting area A2. In this embodiment, the conducting layer 34 may comprise a first sub-conducting layer 340 and a second sub-conducting layer 342, wherein a projection area of the first sub-conducting layer 340 on the substrate 38 is smaller than a projection area of the second sub-conducting layer 342 on the substrate 38. As shown in FIG. 3, the second sub-conducting layer 342 is disposed on the second semiconductor layer 44 and the first sub-conducting layer 340 is disposed on the second sub-conducting layer 342, therefore an overlapped area of the first sub-conducting layer 340 and the second sub-conducting layer 342 forms the first conducting area A1, and a remaining area of the second sub-conducting layer 342 not overlapped with the first sub-conducting layer 340 forms the second conducting area A2. It should be noted that a material of the first sub-conducting layer 340 may be the same to or different from a material of the second sub-conducting layer 342, depending on practical applications.

As shown in FIG. 2, the second electrode 36 has an extension portion 360, wherein the extension portion 360 extends toward the first electrode 32 and the first conducting area A1 overlaps at least a part of the extension portion 360. Since the resistance of the first conducting area A1 is less than the resistance of the second conducting area A2, the current entering the second electrode 36 can be spread uniformly and flow through the second semiconductor layer 44, the light emitting layer 42 and the first semiconductor layer 40 and then exits from the first electrode 32, to reduce the current crowding effect at the tail end of the extension portion 360 (i.e. the end of the extension portion 360 close to the first electrode 32) and enhance the light emitting efficiency of the light emitting component 3.

In an embodiment, a length L of the first conducting area A1 in a direction parallel to the extension portion 360 may be larger than or equal to a half of a total length Lt of the second electrode 36 in the direction parallel to the extension portion 360 to enhance the current spreading effect. In an embodiment, an edge E of the first conducting area A1 may be located between a center C of the extension portion 360 and the first electrode 32 to enhance the current spreading effect.

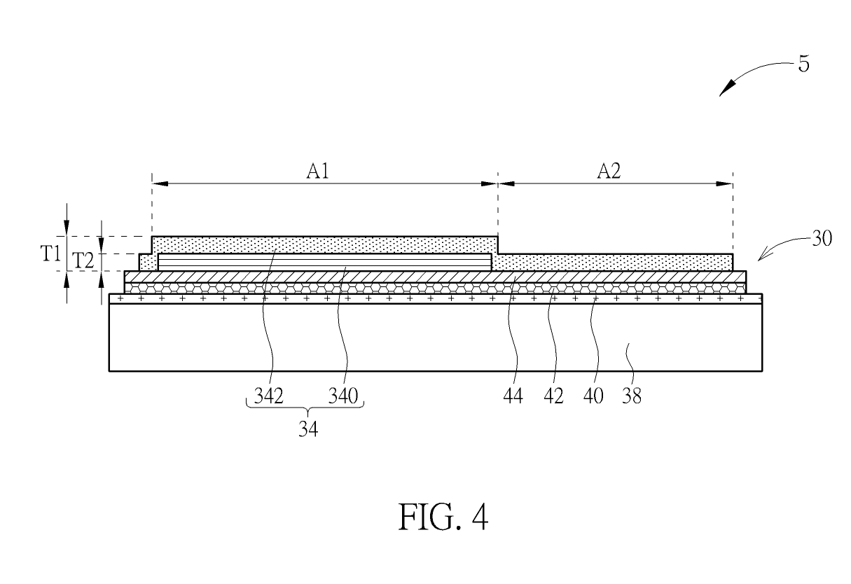

Referring to FIG. 4 along with FIG. 3, FIG. 4 is a schematic cross-sectional view illustrating a light emitting component 5 according to a second embodiment of the disclosure. The main difference between the light emitting component 5 and the aforementioned light emitting component 3 is that, in the light emitting component 5, the first sub-conducting layer 340 is disposed on the second semiconductor layer 44 and the second sub-conducting layer 342 is disposed on the first sub-conducting layer 340 and the second semiconductor layer 44, therefore an overlapped area of the first sub-conducting layer 340 and the second sub-conducting layer 342 forms the first conducting area A1, and a remaining area of the second sub-conducting layer 342 not overlapped with the first sub-conducting layer 340 forms the second conducting area A2. In other words, in the disclosure, the first sub-conducting layer 340 is disposed on the second sub-conducting layer 342 or the first sub-conducting layer 340 is disposed between the second semiconductor layer 44 and the second sub-conducting layer 342, depending on practical applications.

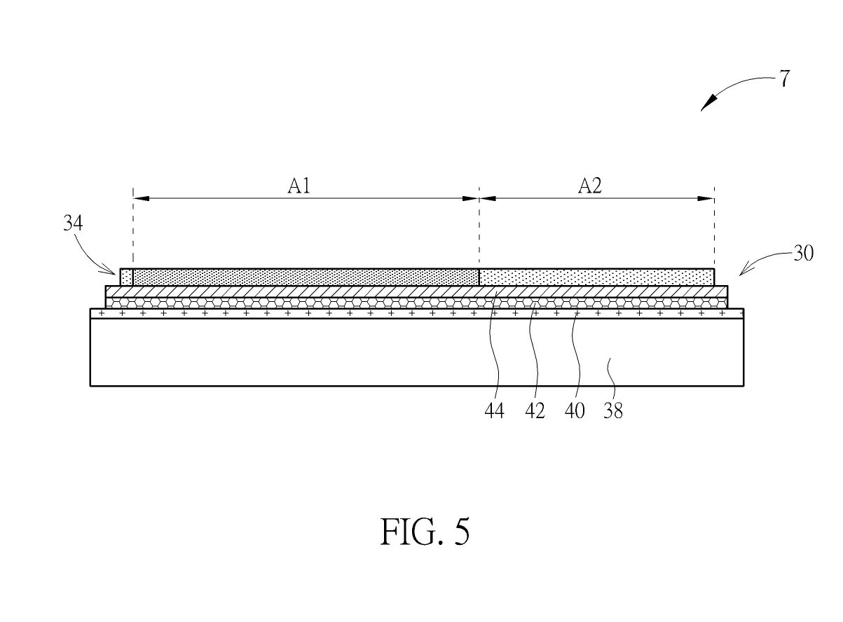

Referring to FIG. 5 along with FIG. 3, FIG. 5 is a schematic cross-sectional view illustrating a light emitting component 7 according to a third embodiment of the disclosure. The main difference between the light emitting component 7 and the aforementioned light emitting component 3 is that, in the light emitting component 7, the first conducting area A1 and the second conducting area A2 of the conducting layer 34′ have the same thicknesses, wherein a dopant concentration of the first conducting area A1 is larger than a dopant concentration of the second conducting area A2, therefore a resistance of the first conducting area A1 is smaller than a resistance of the second conducting area A2. For example, if a material of the conducting layer 34′ is ITO, a concentration of Sn doped in ITO can be defined as the aforementioned dopant concentration. In other words, in the disclosure, in order to achieve that the resistance of the first conducting area A1 is smaller than the resistance of the second conducting area A2, the thickness of the first conducting area A1 may be larger the thickness of the second conducting area A2 or the dopant concentration of the first conducting area A1 may be larger than the dopant concentration of the second conducting area A2, depending on practical applications.

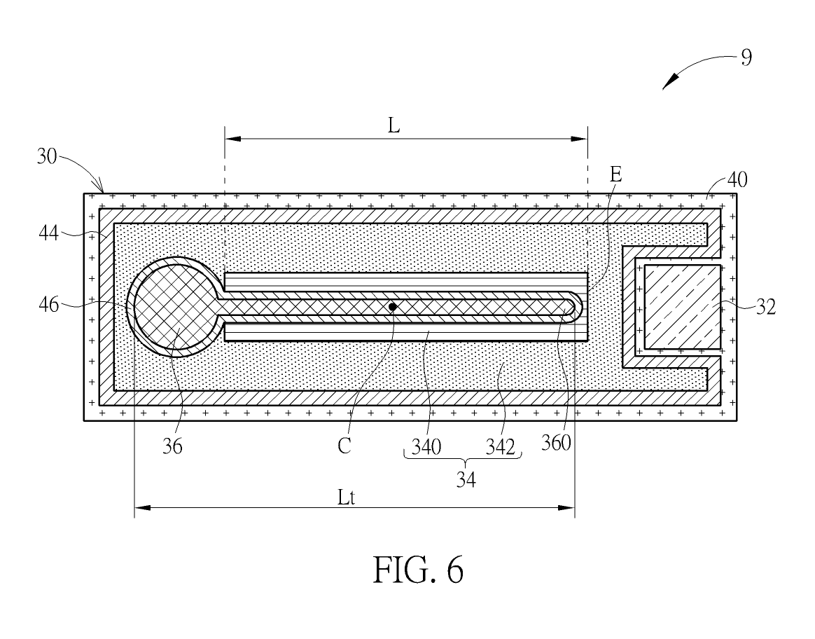

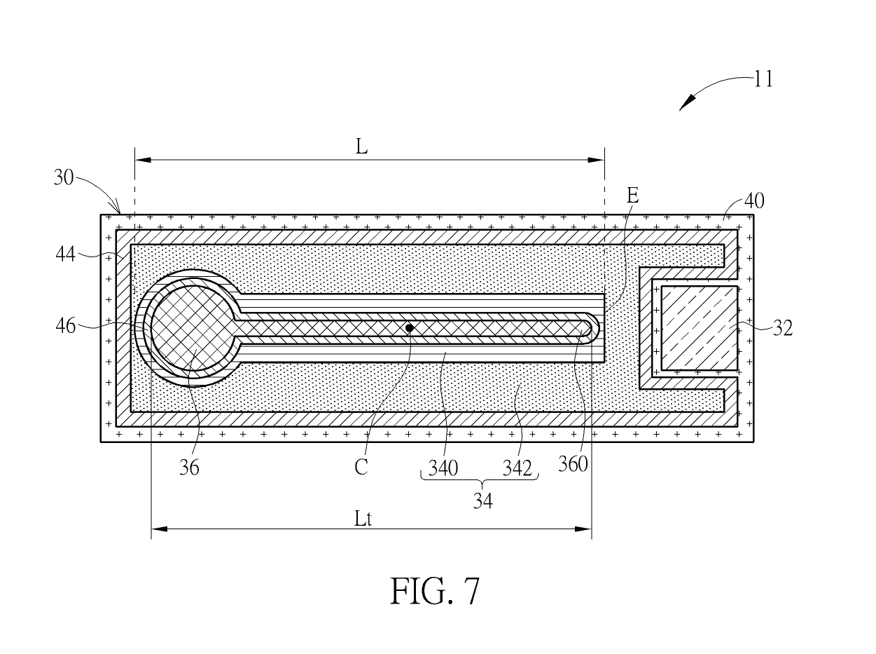

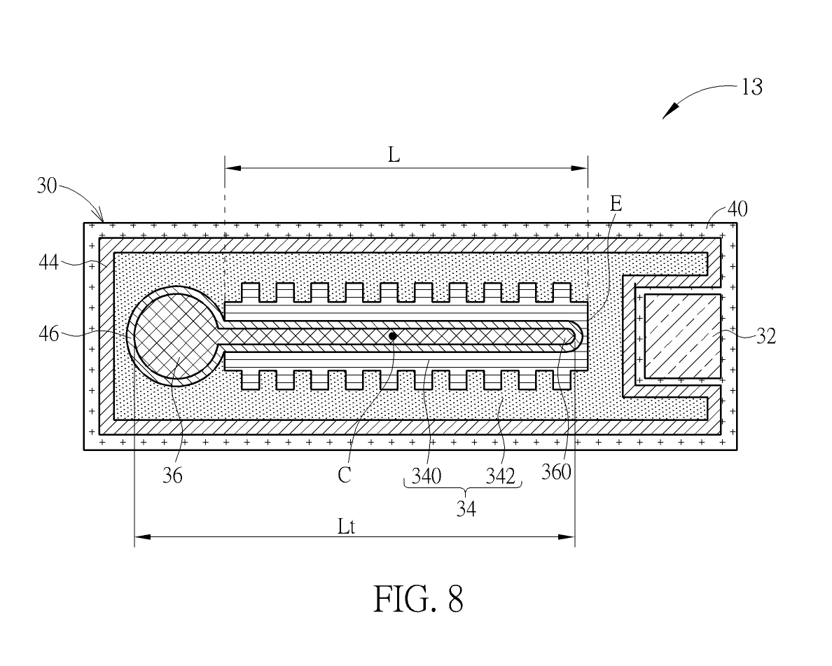

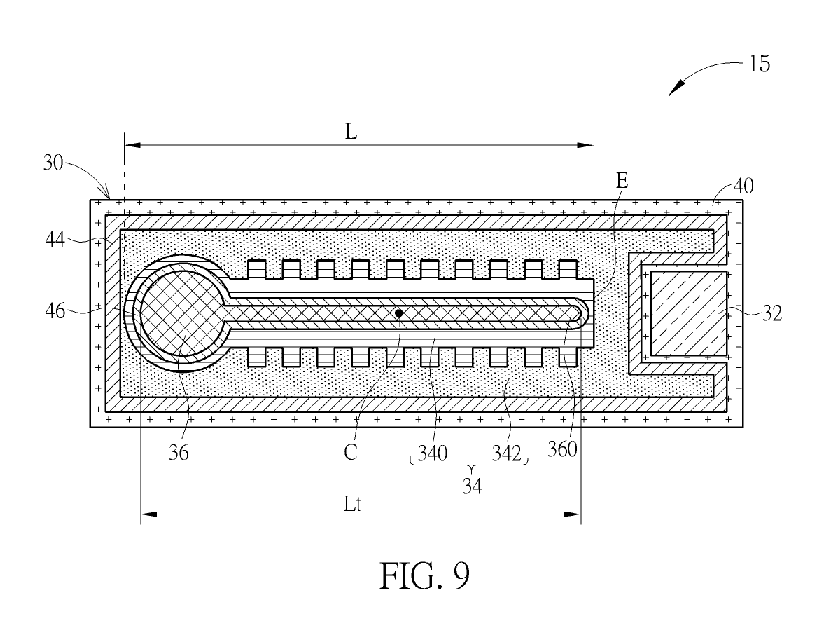

Referring to FIGS. 6 to 9 along with FIG. 2, FIG. 6 is a schematic top view illustrating a light emitting component 9 according to a fourth embodiment of the disclosure, FIG. 7 is a schematic top view illustrating a light emitting component 11 according to a fifth embodiment of the disclosure, FIG. 8 is a schematic top view illustrating a light emitting component 13 according to a sixth embodiment of the disclosure, and FIG. 9 is a schematic top view illustrating a light emitting component 15 according to a seventh embodiment of the disclosure. In addition to the pattern of the first sub-conducting layer 340 shown in FIG. 2, the disclosure also provides the first sub-conducting layer 340 as the patterns shown in FIGS. 6 to 9. In other words, the disclosure provides the first sub-conducting layer 340 as the patterns shown in FIGS. 2 and 6-9 or other patterns, depending on practical applications, not limited to the pattern shown in FIG. 2. In the embodiments shown in FIGS. 6 to 9, the disclosure provides that the first sub-conducting layer 340 is disposed on the second sub-conducting layer 342 (as shown in FIG. 3) or the first sub-conducting layer 340 is disposed between the second semiconductor layer 44 and the second sub-conducting layer 342, depending on practical applications (as shown in FIG. 4).

As the above mentioned, in the disclosure, the conducting layer is divided into the first conducting area with smaller resistance and the second conducting area with larger resistance, and the first conducting area with smaller resistance overlaps at least a part of the extension portion of the second electrode. Accordingly, the current entering the second electrode can be spread uniformly and the light emitting efficiency can be enhanced. It should be noted that, in the disclosure, in order to achieve that the resistance of the first conducting area is smaller than the resistance of the second conducting area, the thickness of the first conducting area may be larger the thickness of the second conducting area or the dopant concentration of the first conducting area may be larger than the dopant concentration of the second conducting area, depending on practical applications.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting component comprising:
an epitaxial structure comprising a substrate, a first semiconductor layer, a light emitting layer and a second semiconductor layer;
a first electrode disposed on the first semiconductor layer;
a conducting layer, disposed on the second semiconductor layer, comprising a first conducting area and a second conducting area, a resistance of the first conducting area being smaller than a resistance of the second conducting area; and
a second electrode, disposed on the conducting layer, having an extension portion toward the first electrode, the first conducting area overlapping at least a part of the extension portion.

2. The light emitting component of claim 1, wherein a thickness of the first conducting area is larger a thickness of the second conducting area.

3. The light emitting component of claim 1, wherein the conducting layer comprises a first sub-conducting layer and a second sub-conducting layer, a projection area of the first sub-conducting layer on the substrate is smaller than a projection area of the second sub-conducting layer on the substrate, and an overlapped area of the first sub-conducting layer and the second sub-conducting layer forms the first conducting area, and a remaining area of the second sub-conducting layer not overlapped with the first sub-conducting layer forms the second conducting area.

4. The light emitting component of claim 3, wherein the second sub-conducting layer is disposed on the second semiconductor layer, and the first sub-conducting layer is disposed on the second sub-conducting layer.

5. The light emitting component of claim 3, wherein the first sub-conducting layer is disposed on the second semiconductor layer, and the second sub-conducting layer is disposed on the first sub-conducting layer and the second semiconductor layer.

6. The light emitting component of claim 1, wherein a dopant concentration of the first conducting area is larger than a dopant concentration of the second conducting area.

7. The light emitting component of claim 6, wherein a material of the conducting layer comprises indium tin oxide.

8. The light emitting component of claim 1, wherein a length of the first conducting area in a direction parallel to the extension portion is larger than or equal to a half of a total length of the second electrode in the direction parallel to the extension portion.

9. The light emitting component of claim 1, wherein an edge of the first conducting area is located between a center of the extension portion and the first electrode.

10. The light emitting component of claim 1, further comprising a current block layer disposed between the conducting layer and the epitaxial structure.
